(19) United States
(12) Patent Application Publication
(10) Pub. No.: US 2004/0076103 A1
(43) Pub. Date: Apr. 22, 2004

(54) Apparatus to remove memory or storage devices from equipment

(75) Inventor: David M. Drouin, Milpitas, CA (US)

Correspondence Address: MICHAEL B. EINSCHLAG, ESQ., 25680 FERNHILL DRIVE, LOS ALTOS HILLS, CA, 94024, US

(73) Assignee: Riospring, Inc., Milpitas, CA

(21) Appl. No.: 10/688,219

(22) Filed: Oct. 16, 2003

Related U.S. Application Data
(60) Provisional application No. 60/420,634, filed on Oct. 22, 2002.

(51) Int. Cl. G11B 33/02; G06F 1/16; H05K 5/00; H05K 7/00

(52) U.S. Cl. 369/75.1; 361/685

(57) ABSTRACT

One embodiment of the present invention is a small form factor disk drive for use in an appliance, which disk drive includes: (a) a connector side, a removal side, and a lateral side; and (b) a gripping mechanism affixed to a lateral side of the disk drive; wherein a portion of the gripping mechanism extends beyond the removal side.

This application claims the benefit of U.S. Provisional Application No. 60/420,634, filed on Oct. 22, 2002, which is incorporated herein by reference.

### TECHNICAL FIELD OF THE INVENTION

One or more embodiments of the present invention relate generally to apparatus to remove a memory or storage device from equipment such as, for example and without limitation, appliances.

### BACKGROUND OF THE INVENTION

There is a growing market demand for appliances in the form of consumer products like digital consumer products such as, for example and without limitation, digital cameras, personal digital assistants (“PDA”), smart phones, and so forth. These digital consumer products utilize memory and/or storage devices such as, for example and without limitation, compact flash memory, memory stick, smart media, and miniature hard disk drives. Consumers are demanding that such memory and/or storage devices provide ever increasing amounts of storage.

Small form factor memory and storage devices such as those, for example and without limitation, that conform to the “CF+ and Compact Flash Specification,” Revision 2, May 2003 issued by CompactFlash Association, Palo Alto, Calif. are regularly installed in, and removed from, various equipment such as, for example and without limitation, appliances. For example and without limitation, compact flash devices serve to store pictures taken by digital cameras, and are regularly installed in, and removed from, such digital cameras. Because of this, ease of installation and removal of such small form factor devices is a key feature for user convenience and satisfaction.

However, such compact flash form factor storage devices are not ergonomically designed. As is well known, current such small form factor memory and storage devices are notoriously difficult to remove from some host appliances (for example and without limitation, digital cameras) due to their small size and a lack of surfaces available for gripping adequately. For example, it is difficult to remove a compact flash card from a digital camera because the card typically does not protrude far enough from the camera body when ejected to provide enough gripping room for a user's fingers to grab on and remove it from the camera. As a result, users often use a foreign object such as, for example and without limitation, tweezers or a small screwdriver to help pry the compact flash card out of the camera. This problematic in that it is inconvenient and may lead to damaging the storage device as well as the digital consumer product in which it is used.

In addition to the above, the problem entailed in removing such small form factor devices is further complicated by the fact that a relatively large force may be required to remove such devices from some equipment or host appliances, and that such devices can be damaged if they are gripped improperly as they are removed. In further addition, individuals having various degrees of dexterity may have difficulty in maintaining a positive grip on such devices (especially when a large force is required to remove the device), thereby causing such devices to fall and be damaged.

In light of the above, there is a need to overcome one or more of the above-identified problems.

### SUMMARY OF THE INVENTION

One or more embodiments of the present invention satisfy one or more of the above-identified needs in the art. In particular, one embodiment of the present invention is a small form factor disk drive for use in an appliance, which disk drive comprises: (a) a connector side, a removal side, and a lateral side; and (b) a gripping mechanism affixed to a lateral side of the disk drive; wherein a portion of the gripping mechanism extends beyond the removal side.

### BRIEF DESCRIPTION OF THE DRAWING

FIGS. 1 and 2 show top and bottom perspective views, respectively, of a small form factor device having a removal apparatus that is fabricated in accordance with one or more embodiments of the present invention.

### DETAILED DESCRIPTION

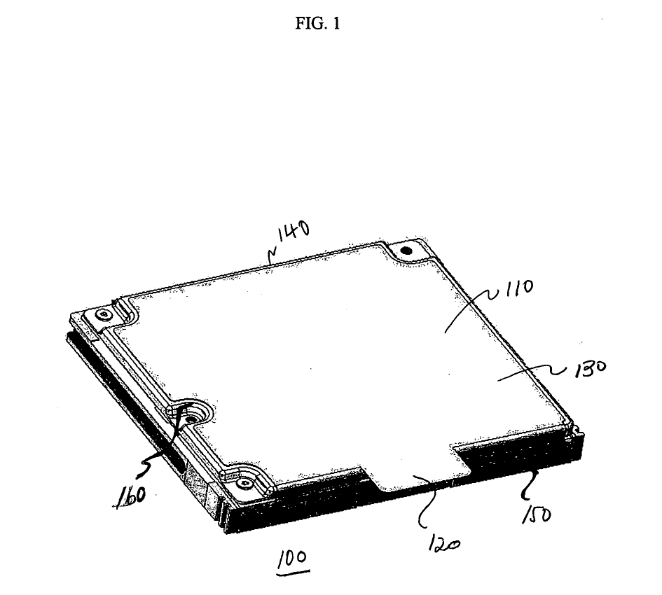

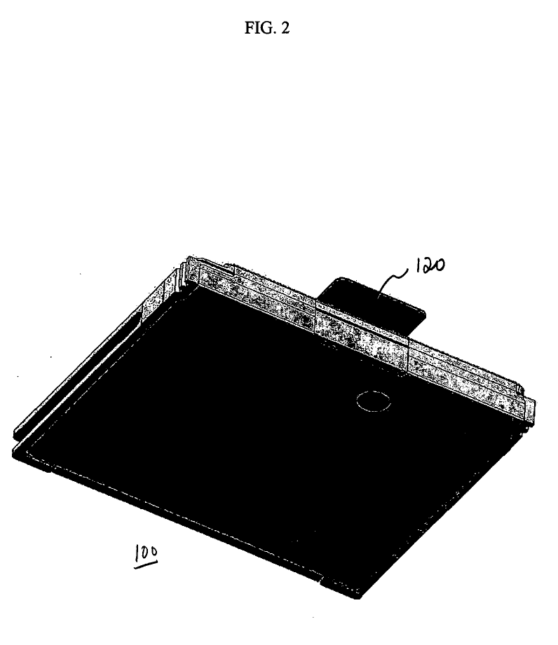

FIGS. 1 and 2 show top and bottom perspective views, respectively, of device 100. As shown in FIGS. 1 and 2, device 100 is a small factor memory or storage device such as, for example and without limitation, a compact flash memory or disk drive. As further shown in FIGS. 1 and 2, device 100 includes connector side 140, removal side 150, and lateral side 160 wherein connector side 140 is a side of device 100 that is inserted into an appliance to connect device 100 with the appliance. As further shown in FIG. 1, removal apparatus 110 that is fabricated in accordance with one or more embodiments of the present invention is affixed to lateral side 160.

As shown in FIGS. 1 and 2, removal apparatus 110 comprises thin pull tab 120 that is easily grasped, and can be used to pull device 100 from a slot in an equipment or host appliance such as, for example and without limitation, a digital camera, once device 100 is released or ejected from the equipment or host appliance in a conventional manner. In accordance with one or more embodiments of the present invention, removal apparatus 110 is comprised of material that is thin enough so that it will not interfere with a normal and intended operation of various doors and covers found in equipment or host appliances in which device 100 is installed or inserted such as, for example and without limitation, digital cameras. In addition, for equipment or host appliances having a door so that, when installed or inserted, device 100 is enclosed in the equipment or host appliance, pull tab 120 is sufficiently thin and flexible so that it is folded by the door as the door closes over pull tab 120. In further addition, pull tab 120 is sufficiently resilient so that it substantially resumes the shape shown in FIGS. 1 and 2 after the door is opened so that a user may grip it for removing device 100.

In accordance with the embodiment shown in FIGS. 1 and 2, removal apparatus 110 includes pull tab 120 and tab body 130. In accordance with one or more such embodiments, tab body 130 may be integrated into a label that is placed on one side of device 100. In addition, and in accordance with one or more such embodiments, tab body 130 may be attached to device 100 by an adhesive. It should be understood that tab body 130 need not cover all or even most of a surface of device 100, it merely needs to cover a sufficiently large area that pull tab 120 may apply a reasonably sufficient force to device 100 so that it can readily be removed from an appliance with which it is used. Further, tab body 130 and pull tab 120 need to be sufficiently strong to enable repeated use of removal apparatus 110. For example, in accordance with Compact Flash mechanical specifications, the minimum tensile strength required is 12 Mpa.

In one particular embodiment, a suitable material for tab body 130 and pull tab 120 is a polyester, for example and without limitation, a white polyester having a thickness of about 0.025 mm that may be obtained under the trade name Type 5779NF from 3M Company of St. Paul, Minn. Further, in accordance with such one particular embodiment, tab body 130 may be affixed to device 100 using an approximately 0.02 mm thickness of adhesive such as an adhesive that may be obtained under the trade name Type 3M 553 from the 3M Company of St. Paul, Minn.

In accordance with one or more further embodiments, pull tab 120 may include protuberances in a form such as, for example and without limitation, ridges to enhance a user's grip, or it may include a pattern of holes to also help enhance a user's grip. In accordance with such one or more further embodiments, the surface of pull tab 120 may be a roughened or a high friction surface to promote ease of retaining a grip wherein the roughness or friction is sufficient to enable a user to overcome forces that retain the disk drive in an appliance with which it is used (suitable amounts of roughness or friction may be determined routinely by one of ordinary skill in the art without undue experimentation).

Although various embodiments that incorporate the teachings of the present invention have been shown and described in detail herein, those skilled in the art can readily devise many other varied embodiments that still incorporate these teachings.

What is claimed is:

1. A small form factor disk drive for use in an appliance, which disk drive comprises:
a connector side, a removal side, and a lateral side; and
a gripping mechanism affixed to a lateral side of the disk drive;
wherein a portion of the gripping mechanism extends beyond the removal side.

2. The small form factor disk drive of claim 1 wherein the gripping mechanism is affixed to cover substantially all of the lateral side.

3. The small form factor disk drive of claim 1 wherein the portion is a pull tab that is strong enough so that it may be gripped to extract the small form factor disk drive from the appliance.

4. The small form factor disk drive of claim 3 wherein the pull tab is thin enough not to interfere with normal operation of the appliance.

5. The small form factor disk drive of claim 4 wherein the pull tab is flexible enough to be folded by a door of the appliance when it is inserted therein.

6. The small form factor disk drive of claim 5 wherein the pull tab is resilient that it resumes it shape after is the door is opened.

7. The small form factor disk drive of claim 1 wherein the gripping mechanism is affixed with an adhesive.

8. The small form factor disk drive of claim 1 wherein the gripping mechanism is about 0.025 mm thick.

9. The small form factor disk drive of claim 3 wherein the pull tab includes protuberances.

10. The small form factor disk drive of claim 3 wherein a surface of the pull tab has high friction.
